(19) United States
(12) Patent Application Publication
(10) Pub. No.: US 2014/0266159 A1
(43) Pub. Date: Sep. 18, 2014

(54) HIGH TEMPERATURE HALL SENSOR FOR MAGNETIC POSITION SENSING

(71) Applicant: Ohio State Innovation Foundation, Columbus, OH (US)

(72) Inventors: Joseph P. Heremans, Upper Arlington, OH (US); Roberto C. Myers, Columbus, OH (US); Yibin Gao, Columbus, OH (US); Zihao Yang, Columbus, OH (US)

(21) Appl. No.: 14/211,990

(22) Filed: Mar. 14, 2014

Related U.S. Application Data
(60) Provisional application No. 61/787,492, filed on Mar. 15, 2013.

(51) Int. Cl. G01R 33/00; G01R 33/07

(52) U.S. Cl. CPC G01R 33/0082; G01R 33/07
USPC 324/207.2

(57) ABSTRACT

A position sensor comprises a group III-nitride Hall effect sensor arranged to measure magnetic field from a magnet wherein the group III-nitride Hall effect sensor and the magnet are arranged to move relative to one another in response to movement of an element whose motion is to be monitored. The electrically conductive layer of the group III-nitride Hall effect sensor may comprise a two-dimensional electron gas (2DEG) defined by an AlₓGa₁₋ₓN/GaN interface where x>0 and in some embodiments x=1 (i.e. an A1N/GaN interface). Disclosed position measurement methods comprise measuring position or speed of the element being monitored using such a position sensor in an environment at a temperature of at least 300° C., and in some embodiments at least 350° C.

This application claims the benefit of U.S. Provisional Application No. 61/787,492 filed Mar. 15, 2013 and titled “HIGH TEMPERATURE HALL SENSOR FOR MAGNETIC POSITION SENSING”. U.S. Provisional Application No. 61/787,492 filed Mar. 15, 2013 and titled “HIGH TEMPERATURE HALL SENSOR FOR MAGNETIC POSITION SENSING” is incorporated herein by reference in its entirety

This invention was made with Government support under grant/contract no. CBET-1133589, awarded by the National Science Foundation (NSF). The government has certain rights in the invention.

### BACKGROUND

The following relates to the high temperature positioning arts, high temperature position sensing arts, and related arts.

High temperature position sensing applications include, by way of illustrative example, magnetostatic crankshaft and camshaft position sensors, which are used (again by way of illustrative example) to control ignition and valve timing in variable valve timing engines of automobiles and other vehicles. In such sensor applications, a magnetic field sensor is typically mounted on a permanent magnet, and a toothed wheel made out of a ferromagnetic metal (like in a steel shaft) rotates in front of it. As the teeth pass, the magnetic field between the magnet and the wheel is modulated, and the magnetic field sensor detects this modulation. When a pattern is encoded in the teeth, an accurate angular position detector can be implemented. These position sensing systems are robust against wear and contamination as compared with optical or resistive rotation encoders, and are well-suited for use in internal combustion engines, gas turbines, and the like.

Commerically available Hall Effect magnetic field sensors are usually based on silicon, InSb, or InAs, and are generally limited to no more than 150° C. For higher temperature operation above 170-200° C., it is contemplated to employ GaAs Hall sensors or heavily doped narrow-bandgap InSb or InAs magnetoresistors grown on an insulating GaAs substrate. See, e.g. J. P. Heremans, “Solid state magnetic sensors and applications”, J. Phys. D: Appl. Phys. volume 26 pages 1149-1168 (1993).

### BRIEF DESCRIPTION

In accordance with some illustrative embodiments disclosed herein, a position sensor comprises a magnet and a group III nitride Hall effect sensor. The magnet and the group III nitride Hall effect sensor are arranged respective to each other and respective to an element to be monitored such that movement of the element to be monitored changes the magnetic field of the magnet passing through the group III nitride Hall effect sensor. In some embodiments the magnet is mounted to move in response to movement of the element to be monitored and the group III-nitride Hall effect sensor is mounted to not move regardless of movement of the element to be monitored. In some embodiments both the magnet and the group III-nitride Hall effect sensor are mounted to not move regardless of movement of the element to be monitored, and the magnetic position sensor further includes magnetic material disposed on the element to be monitored such that movement of the magnetic material as the element to be monitored moves changes the magnetic field of the magnet passing through the group III-nitride Hall effect sensor. In some such embodiments the element to be monitored comprises a rotating wheel and the magnetic material comprises or is disposed on teeth of the rotating wheel.

In some illustrative embodiments disclosed herein, in a position sensor as set forth in the immediately preceding paragraph the group III-nitride Hall effect sensor comprises a heterointerface defining a two-dimensional electron gas (2DEG), and the magnetic position sensor further comprises an electronic data processing device configured to inject electric current through the 2DEG and measure a Hall voltage induced across the 2DEG responsive to the injected electric current and a magnetic field oriented transverse to the 2DEG. The heterointerface defining the 2DEG may be an AlₓGa₁₋ₓN/GaN interface where x>0, and in some embodiments the hetero interface defining the 2DEG is an AlN/GaN interface. In some embodiments the electronic data processing device is further configured to compute the magnetic field oriented transverse to the 2DEG based on a ratio of the Hall voltage and the injected electric current. In some embodiments the electronic data processing device is further configured to compute a position of the element to be monitored based on the Hall voltage and the injected electric current.

In accordance with some illustrative embodiments disclosed herein, a method comprises disposing an element to be monitored in an environment at a temperature of at least 300° C., and measuring a position of the element to be monitored using a position sensor including a magnet and a group III-nitride Hall effect sensor arranged respective to each other and respective to the element to be monitored such that movement of the element to be monitored changes the magnetic field of the magnet passing through the group III-nitride Hall effect sensor. In some embodiments the disposing operation comprises disposing the element to be monitored in an environment at a temperature of at least 350° C. In some embodiments, the method further comprises measuring the temperature, and compensating for a temperature-dependent offset of the Hall voltage output by the group III-nitride Hall effect sensor based on the measured temperature. In some such embodiments measuring the temperature comprises measuring the sheet resistance of the group III-nitride Hall effect sensor, and determining the temperature based on the measured sheet resistance. In embodiments, the method further comprises measuring the temperature, and compensating for a temperature dependence of the magnetic field of the magnet based on the measured temperature.

### BRIEF DESCRIPTION OF THE DRAWINGS

Unless otherwise noted, the drawings are not to scale or proportion. The drawings are provided only for purposes of illustrating preferred embodiments and are not to be construed as limiting.

FIG. 1 diagrammatically shows an illustrative linear position sensor that measures a gap between two elements; the lower inset of FIG. 1 shows a diagrammatic perspective view of an illustrative group III-nitride Hall effect sensor.

FIG. 2 plots experimentally measured sheet resistance versus temperature for an AlN/GaN 2DEG Hall effect sensor fabricated as described herein.

FIG. 3 plots experimentally measured Hall signal versus magnetic field at five temperatures in the range 27° C. to 350° C. for an AlN/GaN 2DEG Hall effect sensor fabricated as described herein.

FIG. 4 diagrammatically shows an illustrative position sensor configured to measure the position of a rotating wheel.

FIG. 5 diagrammatically shows an illustrative position sensor configured to measure the position of a rotating arm that rotates about a shaft.

FIG. 6 diagrammatically shows an illustrative brushless motor control incorporating a rotary position sensor.

### DETAILED DESCRIPTION OF PREFERRED EMBODIMENTS

Disclosed herein are magnetic position sensors that employ Hall effect sensors (also called Hall sensors herein) comprising group III-nitride semiconductor materials for the electrically conductive region. In an illustrative example, a two-dimensional electron gas (2DEG) is formed at a heterojunction, e.g. an AlN/GaN heterojunction or an AlₓGa₁₋ₓN/GaN heterojunction (where x>0, and embodiments with x=1 correspond to AlN/GaN heterojunctions). As used herein, a two-dimensional electron gas (2DEG) is understood to be layer of electrons that are free two move in two dimensions but are confined in a third dimension. The confinement may be produced, for example, at an interface between dissimilar materials, at a delta doping, in a quantum well or superlattice, or so forth. The confinement in the third dimension may be imperfect, and the 2DEG may in general have some finite thickness, and/or may have a gradual boundary or transition along the confined third dimension.

The Hall effect is the voltage difference (known as the Hall voltage) generated in the transverse direction of applied electrical current under the influence of magnetic field perpendicular to both the current and the Hall voltage. The Hall voltage is a result of the electrical current path being bended by Lorentz force exerted by the external magnetic field. The Hall voltage

$${V}_{H} = {R}_{H} \frac{I \cdot B}{d}$$

where V_{H} is the Hall voltage, I is the applied electric current, B is the (transverse) magnetic field, and d is the thickness (in the direction of the magnetic field B) of the electrically conductive layer that carries the current I. The term R_{H} is known as the Hall coefficient, and is related to the carrier concentration in the electrically conductive layer of thickness d. The foregoing equation can be solved for the magnetic field value yielding

$$B = \frac{d}{{R}_{H}} \cdot \frac{{V}_{H}}{I}$$

where the ratio d/R_{H} can be determined based on the device geometry and material properties. From the transverse current-voltage (I-V) curve and a known applied electric current I, the magnetic field can thus be calculated. In position sensor applications, the slope ΔR=ΔV/ΔI of the I-V curve can be used in place of V_{H}/I to eliminate zero magnetic field voltage offset commonly observed as a result of geometric misalignment of voltage leads. Moreover, in typical position sensor applications the absolute magnitude of B is typically less important than the modulation of B as a function of time. Accordingly, quantitative knowledge of the ratio d/R_{H} may not be needed to utilize the position sensor, or alternatively d/R_{H} can be measured empirically from the I-V curve for a known (calibration) applied magnetic field.

An advantage of position sensors employing group III-nitride Hall effect magnetic field sensor components as disclosed herein is that these position sensors are operable at high temperature, e.g. 300° C. or higher, and in some embodiments 350° C. or higher. Accordingly, these position sensors are suitable for use in applications such as monitoring oil-well drilling equipment or transmission systems in machinery, and in internal combustion (IC) engines.

With reference to FIG. 1 (inset), an illustrative group III-nitride Hall sensor 10 is grown by a suitable technique such as molecular beam epitaxy (MBE) or metal-organic chemical vapor deposition (MOCVD) on a suitable substrate 12 such as silicon carbide (e.g., SiC:6H where the appended “:6H” denotes crystallographic orientation of the epitaxy surface). The following conventional notation (e.g. conventional chemical symbols) is employed herein: GaN denotes gallium nitride; AlN denotes aluminum nitride; AlₓGa₁₋ₓN denotes a ternary alloy of GaN and AlN with the fraction of AlN being x and the fraction of GaN being 1-x; Ti denotes titanium; Al denotes aluminum; Au denotes gold; SiC denotes silicon carbide; and so forth. In growing the group III-nitride Hall sensor 10, suitable techniques are suitably employed during the epitaxial growth to suppress formation of dislocations, anti-phase boundaries, and other defects, such as in the illustrative example growing an AlN nucleation layer 14 and a rough GaN buffer layer 16 to accommodate the lattice mismatch between the substrate 12 and smooth GaN 18. In the illustrative Hall sensor 10, the conductive layer of (effective) thickness d is an AlN/GaN two-dimensional electron gas (2DEG) 20 formed at an interface between the smooth GaN 18 and an AlN capping layer 22 deposited on top of the smooth GaN 18. It should be noted that the 2DEG 20 can be thought of as having some finite “effective” thickness d corresponding to the electron concentration profile along the direction transverse to the AlN/GaN interface. In practice, however, it is the ratio d/R_{H} that matters for analyzing the Hall sensor output in the context of a magnetic position sensor, and again this ratio can be determined by empirical calibration (or may be irrelevant if only the time modulation of the Hall sensor output is of interest, e.g. as in a speed sensor).

After epitaxial growth of the group III-nitride heterostructure, a suitable Hall sensor geometry is defined using photolithography or another patterning technique. It is then etched as a Hall-bar mesa into the AlN/GaN structure by subsequent chlorine-based dry etching. In the illustrative Hall sensor 10, a conventional Hall bar is defined; however, it is also contemplated to employ a Van Der Pauw geometry or other Hall sensor geometry. Typically, a Hall bar provides the most accurate Hall effect measurement compared with other Hall geometries. Electrical contacts 24 are formed during the Hall sensor device fabrication using known techniques. In the illustrative Hall sensor 10, Ti/Al/Ti/Au metal stacks 24 are employed as the electrical contacts. A rapid thermal anneal at 750° C. for 30 seconds is performed after evaporation of the Ti/Al/Ti/Au metal stack.

In FIG. 1 (inset), the Hall voltage V_{H} is across the resistance R_{xy} indicated in FIG. 1. On the other hand, the sheet resistance corresponds to the resistance Rₓₓ indicated in FIG. 1 (inset). In general, this sheet resistance scales with temperature (see FIG. 2) and hence can serve as a mechanism for measuring the temperature of the Hall sensor.

Although an AlN/GaN 2DEG 20 is employed as the electrically conductive layer in the illustrative Hall sensor 10 shown in FIG. 1 (inset), other configurations are contemplated. For example, the 2DEG can be formed at an interface of lower aluminum content, i.e. an AlₓGa₁₋ₓN/GaN interface with x<1. As another illustrative variant, it is contemplated to replace the 2DEG with a finite quantum well defined by a lower bandgap material (e.g. GaN) confined by wider-bandgap barriers (e.g. AlN). However, in the group III-nitride system the electron confinement is dominated by stress-induced piezoelectric electric polarization and by spontaneous polarization, making the illustrative AlN/GaN interface an effective electron confinement structure. It is also contemplated to have two or more conductive layers, for example employing a . . . GaN/AlN/GaN/AlN/GaN . . . superlattice to form multiple parallel 2DEG layers. Still further, it is contemplated to encapsulate the group III-nitride Hall sensor (or at least the 2DEG-defining layers) by a dielectric encapsulant or passivation layer.

The group III-nitride materials have high melting points, large energy gaps, and are resistive to oxidation. However, the electron confinement provided by the stress-induced and spontaneous electric polarization at the AlN/GaN interface is expected to exhibit substantial temperature-dependence, because thermal expansion is expected to result in thermally induced stresses that could substantially change the polarization. This is expected to make such devices unsuitable for use in high temperature position sensors. Surprisingly, however, experiments performed by the inventors have established that these devices exhibit limited temperature dependence, and in fact are well suited for use in a position sensor. Without being limited to any particular theory of operation, this limited temperature dependence is believed to be due to the minimized piezoelectric polarization contribution obtained in the devices as described by capping the device with a partially relaxed AlN layer, e.g. the AlN capping layer 22 in the illustrative Hall sensor 10.

The tested devices were grown by plasma assisted molecular beam epitaxy. Device structures were grown along the (0001) direction on 6H—SiC (Si face) template and consisted of the following layers, 70 nm unintentionally doped AlN nucleation layer/140 nm rough unintentionally doped GaN/300nm unintentionally doped smooth GaN/5 nm unintentionally doped AlN capping layer. The AlN capping layer and smooth GaN layer were grown under slightly Al rich intermediate regime (Al/N flux ratio ˜1) and droplet regime (Ga/N flux ratio ˜2.6) separately at 710° C. The rough GaN layer was grown under Ga rich intermediate regime (Ga/N flux ratio-1.7) at 730° C. while the AlN nucleation layer was grown under nitrogen rich regime (Al/N flux ratio˜0.6) at 780° C.

FIGS. 2 and 3 show experimental Hall effect measurements on these devices, with FIG. 2 showing the sheet resistance as a function of temperature, and FIG. 3 showing the Hall signal as a function of temperature, with both data sets being measured up to 350° C. The Hall signal was measured using a direct-current (d.c.) applied electrical current of 10 microamperes and measuring the transverse voltage using a d.c. voltmeter. Other measurements techniques can be used. For example, an alternating current (a.c.) impedance bridge, or an a.c. current source and a lock-in amplifier used as a frequency-selective phase-sensitive voltmeter on the transverse voltage probes. As seen in FIG. 3, the slope of the Hall curves does not change as a function of temperature between 27° C. and 350° C. The offsets do change with temperature, but this can be compensated for. If the position sensor works by modulating the magnetic field, the changes in magnetic field are likely to be much faster than the changes in temperature. Even if the temperature effects cannot be filtered out, the resistance of the sample can be measured (as per FIG. 2, corresponding to the sheet resistance in the Rₓₓ orientation shown in FIG. 1) and used as a thermometer and a lookup table then used to compensate the temperature-dependent offset. Alternatively, a thermocouple or other temperature sensor can be used to measure the temperature.

In one operational mode, the Hall voltage is determined by applying current, measuring the voltage, then reversing the current, measuring the voltage again, and taking the difference between the tw measurements to eliminate parasitic thermoelectric effects. The slope ΔR is obtained from the two data points taken at opposite current directions. From FIG. 3, the ratio d/R_{H} is obtained at the temperature determined by resistivity (as described with reference to FIG. 2, or by a separate temperature sensor), and magnetic field is calculated as

$$B = \frac{d}{{R}_{H}} \cdot \frac{{V}_{H}}{I} .$$

The group III-nitride Hall sensors provide reliable performance as magnetic sensor components at temperatures of at least 350° C. (see FIGS. 2 and 3). It is reasonably expected that the disclosed Hall sensor employing an AlN/GaN 2DEG should function well up to 500° C. with high reliability. The AlN/GaN material vacuum starts to decompose at above 750° C., and can be epitaxially grown at temperatures close to this, e.g. at 730° C. Due to the wide band gap of the material, the carrier density is not expected to change significantly between room temperature and the decomposition temperature, so the Hall sensor is expected to be operational in the position sensing application at least up to 700° C. with the use of suitable high temperature electrodes.

In general, the position sensor includes the group III-nitride hall sensor arranged to monitor magnetic field change due to motion of an element being directly monitored or due to motion of an element (e.g. a gear) mechanically engaging the element being monitored. In one class of position sensor configurations, the magnetic field is generated by a permanent magnet mounted at a fixed location and magnetic field modulation is provided by an element of magnetic material (e.g. ferromagnetic material) disposed on the in-motion element whose position is being monitored and arranged to magnetically engage the magnet, with the AlN/GaN Hall sensor located between the ferromagnetic material and the permanent magnet. In another class of position sensor configurations, the magnetic field is generated by a permanent magnet mounted on the in-motion element whose position is being monitored and the Hall sensor is located in a stationary position proximate to the in-motion element. The permanent magnet applies a magnetic field that has little temperature-dependence, which, up to 500° C., can be achieved with samarium-cobalt magnets. Should there be a drift in magnetic field with temperature, in the embodiment in FIG. 4 the temperature of the magnet/sensor can be measured by monitoring the resistance of the Hall probe, and compensating for temperature as described previously herein. Although permanent magnets are generally advantageous as they require no electrical power input, it is also contemplated to substitute an electromagnet for the permanent magnet. The motion being monitored may, in general, be rotary or linear motion.

With reference to FIGS. 1 and 4-6, some non-limiting illustrative position sensor embodiments are described.

FIG. 1 (main drawing) illustrates a linear position sensor 30 that measures a gap G between a first element (not shown) monitored by a first AlN/GaN Hall sensor 10₁ and a second element (not shown) monitored by a second AlN/GaN Hall sensor 10₂. A magnet 32 outputs a magnetic field having a magnitude B₁ at the first Hall sensor 10₁ and lower magnitude B₂ at the second Hall sensor 10₂ which is further away from the magnet 32 than the first Hall sensor 10₁. Analog/digital (A/D) converters 34, 36 deliver drive current I to each Hall sensor 10₁, 10₂ and read the Hall voltage V_{H} output by each Hall sensor 10₁, 10₂, and an electronic data processing device 38 applies the equation

$$B = \frac{d}{{R}_{H}} \cdot \frac{{V}_{H}}{I}$$

to compute respective magnetic field values B₁ and B₂. Based on a known (e.g., measured or calculated) magnetic field-versus-distance curve 40 which is expected to decrease monotonically with increasing distance from the magnet, the electronic data processing device 38 computes the positions of the first and second elements from the values B₁ and B₂. In general, the electronic data processing device 38 may be a suitably programmed computer, or a dedicated Hall sensor readout device, or so forth.

With reference to FIG. 4, a rotary position sensor 50 includes a magnet 52 in proximity with a wheel 54 having ferromagnetic teeth 56 (or teeth of another magnetic material). This wheel 54 may be made entirely of ferromagnetic material (e.g., steel) or may have a hub 58 of non-ferromagnetic material with only the teeth 56 being made of ferromagnetic material. Two AlN/GaN Hall sensors 60₁, 60₂ are mounted on the face of the magnet 52 proximate to the wheel 54. In the position of the wheel 54 illustrated in FIG. 4, the left AlN/GaN Hall sensor 60₁ has a ferromagnetic tooth 56₁ in close proximity. As a consequence, a strong magnetic flux flows between the magnet 52 and the proximate ferromagnetic tooth 56₁ corresponding to a relatively large magnetic field B₁ that is sensed by the left AlN/GaN Hall sensor 60₁. On the other hand, in the position of the wheel 54 illustrated in FIG. 4, the right AlN/GaN Hall sensor 60₂ has no ferromagnetic tooth in close proximity. As a consequence, a low magnetic flux flows through the right AlN/GaN Hall sensor 60₂ corresponding to a relatively low magnetic field B₂ that is sensed by the right AlN/GaN Hall sensor 60₂. As the wheel 54 rotates counterclockwise about its axis 64 (as shown in illustrative FIG. 4), successive teeth 56 pass across the left AlN/GaN Hall sensor 60₁ followed by the right AlN/GaN Hall sensor 60₂, generating magnetic field pulses that are detected by the Hall sensors 60₁, 60₂ so as to measure rotation speed of the wheel 54. The illustrative teeth 56 are uniform, but if they have leading or lagging sloped edges or other spatial encoding these magnetic field pulses may also be used to determine absolute wheel position and/or direction of the rotation (if the wheel can rotate both counterclockwise and clockwise). For example, an illustrative alternative coding edge 66 (shown in dashed line on only one tooth for illustrative purposes) can be used to provide encoding of the magnetic field pulses. Although not illustrated in FIG. 4, a data processing device and A/D circuitry are suitably included to drive current through the Hall sensors and read the Hall voltages.

With reference to FIG. 5, another rotary position sensor 70 is shown. In this embodiment a magnet 72 is mounted on a rotary element which comprises a rotating arm 74 that rotates about a shaft 76. The end of the rotating arm 74 distal from the shaft 76 includes the magnet 72 that, as the rotating arm 74 rotates in the illustrative counter-clockwise direction, successively passes by a first AlN/GaN Hall sensor 80₁ and then a second AlN/GaN Hall sensor 80₂. Absolute angular position information of the rotating arm 74 about the shaft 76 is provided: when the magnet 72 is aligned with the first AlN/GaN Hall sensor 80₁, the magnetic field at that sensor (i.e. the B₁ pulse) is at its peak; when the magnet 72 is aligned with second AlN/GaN Hall sensor 80₂, its magnetic field B₂ pulse is at its peak. An interpolation (not necessarily linear) between the two measured magnetic fields B₁ and B₂ as measured by the respective Hall sensors 80₁, 80₂ then provides information about the position of the magnet 72 vis-a-vis the two Hall sensors 80₁, 80₂, and therefore about the angular position of the rotating arm 74 about the shaft 76.

With reference to FIG. 6, an illustrative brushless motor control incorporating a rotary position sensor is shown. The brushless motor includes a diagrammatically indicated motor rotor 90 and motor stator windings 92 driven by a power supply 94 via associated electronics circuitry 96. The position sensor of FIG. 6 operates similarly to that of the embodiment of FIG. 5, and includes AlN/GaN Hall sensors 100₁, 100₂. Here, the polarity of the Hall voltage V_{H} alternates as the north pole and south pole of the motor rotor 90 successively passes a AlN/GaN Hall sensor, which as per the relationship

$$B = \frac{d}{{R}_{H}} \cdot \frac{{V}_{H}}{I}$$

corresponds to the measured B field reversing polarity.

The embodiments of FIGS. 1 and 4-6 are merely illustrative examples, and the disclosed magnetic position sensors employing group III-nitride Hall sensors can employ numerous other configurations.

The preferred embodiments have been described. Obviously, modifications and alterations will occur to others upon reading and understanding the preceding detailed description. It is intended that the invention be construed as including all such modifications and alterations insofar as they come within the scope of the appended claims or the equivalents thereof.

1. A position sensor comprising:
a magnet; and
a group III-nitride Hall effect sensor;
the magnet and the group III-nitride Hall effect sensor being arranged respective to each other and respective to an element to be monitored such that movement of the element to be monitored changes the magnetic field of the magnet passing through the group III-nitride Hall effect sensor.

2. The position sensor of claim 1 wherein the magnet is mounted to move in response to movement of the element to be monitored and the group III-nitride Hall effect sensor is mounted to not move regardless of movement of the element to be monitored.

3. The position sensor of claim 1 wherein both the magnet and the group III-nitride Hall effect sensor are mounted to not move regardless of movement of the element to be monitored, and the magnetic position sensor further includes magnetic material disposed on the element to be monitored such that movement of the magnetic material as the element to be monitored moves changes the magnetic field of the magnet passing through the group III-nitride Hall effect sensor.

4. The position sensor of claim 3 wherein the element to be monitored comprises a rotating wheel and the magnetic material comprises or is disposed on teeth of the rotating wheel.

5. The position sensor of claim 1 wherein the group III-nitride Hall effect sensor comprises a heterointerface defining a two-dimensional electron gas (2DEG) and the magnetic position sensor further comprises:
an electronic data processing device configured to inject electric current through the 2DEG and measure a Hall voltage induced across the 2DEG responsive to the injected electric current and a magnetic field oriented transverse to the 2DEG.

6. The position sensor of claim 5 wherein the heterointerface defining the 2DEG is an AlₓGa₁₋ₓN/GaN interface where x>0.

7. The position sensor of claim 5 wherein the heterointerface defining the 2DEG is an AlN/GaN interface.

8. The position sensor of claim 5 wherein the electronic data processing device is further configured to compute the magnetic field oriented transverse to the 2DEG based on a ratio of the Hall voltage and the injected electric current.

9. The position sensor of claim 5 wherein the electronic data processing device is further configured to compute a position of the element to be monitored based on the Hall voltage and the injected electric current.

10. A method comprising:
disposing an element to be monitored in an environment at a temperature of at least 300° C.; and
measuring a position of the element to be monitored using a position sensor including a magnet and a group III-nitride Hall effect sensor arranged respective to each other and respective to the element to be monitored such that movement of the element to be monitored changes the magnetic field of the magnet passing through the group III-nitride Hall effect sensor.

11. The method of claim 10 wherein the disposing comprises:
disposing the element to be monitored in an environment at a temperature of at least 350° C.

12. The method of claim 10 wherein the disposing comprises:
disposing the element to be monitored in an environment at a temperature of between 350° C. and 500° C.

13. The method of claim 10, further comprising:
measuring the temperature; and
compensating for a temperature-dependent offset of the Hall voltage output by the group III-nitride Hall effect sensor based on the measured temperature.

14. The method of claim 13 wherein the measuring of the temperature comprises:
measuring the sheet resistance of the group III-nitride Hall effect sensor; and
determining the temperature based on the measured sheet resistance.

15. The method of claim 10, further comprising:
measuring the temperature; and
compensating for a temperature dependence of the magnetic field of the magnet based on the measured temperature.

16. A position sensor comprising:
a magnet;
a group III-nitride Hall effect sensor arranged respective to the magnet and respective to an element to be monitored such that movement of the element to be monitored changes the magnetic field of the magnet passing through the group III-nitride Hall effect sensor; and
an electronic data processing device configured to:
measure a Hall voltage induced in the group III-nitride Hall effect sensor as a function of time in response to an electric current injected into the group III-nitride Hall effect sensor and a magnetic field of the magnet passing through the group III-nitride Hall effect sensor, and
determine a position of the element to be monitored based on the measured Hall voltage as a function of time.

17. The position sensor of claim 16 wherein the group III-nitride Hall effect sensor is arranged respective to the magnet and respective to an element to be monitored such that one of (i) movement of the element to be monitored moves the magnet without moving the group III-nitride Hall effect sensor to change the magnetic field of the magnet passing through the group III-nitride Hall effect sensor and (ii) movement of the element to be monitored moves the group III-nitride Hall effect sensor without moving the magnet to change the magnetic field of the magnet passing through the group III-nitride Hall effect sensor.

18. The position sensor of claim 16 further comprising:
magnetic material disposed on the element to be monitored such that movement of the element to be monitored moves the magnetic material;
wherein the magnet and the group III-nitride Hall effect sensor are mounted so that movement of the element to be monitored does not move the magnet and does not move the group III-nitride Hall effect sensor;
wherein movement of the magnetic material as the element to be monitored moves changes the magnetic field of the magnet passing through the group III-nitride Hall effect sensor.

19. The position sensor of claim 18 wherein the element to be monitored comprises a rotating wheel and wherein:
the magnetic material is disposed on or comprises teeth of the rotating wheel.

20. The position sensor of claim 16 wherein the group III-nitride Hall effect sensor comprises:
a AlₓGa₁₋ₓN/GaN heterointerface where x>0 and x<1;
wherein the Hall voltage is induced in the AlₓGa₁₋ₓN/GaN heterointerface of the group III-nitride Hall effect sensor.

21. The position sensor of claim 20 wherein the group III-nitride Hall effect sensor further comprises:
a capping partially relaxed AlN layer.

22. The position sensor of claim 20 wherein the electronic data processing device is configured to determine the position of the element to be monitored by operations including:
computing a magnetic field oriented transverse to the AlₓGa₁₋ₓN/GaN heterointerface based on a ratio of the measured Hall voltage as a function of time and the electric current injected into the group III-nitride Hall effect sensor; and
determining the position based on the computed magnetic field.

23. The position sensor of claim 16 wherein the element to be monitored is a rotating element including one of (i) the magnet and (ii) magnetic material such that rotation of the rotating element to be monitored generates magnetic field pulses in the magnetic field of the magnet passing through the group III-nitride Hall effect sensor, and wherein the electronic data processing device is configured to:
detect the magnetic field pulses based on the measured Hall voltage as a function of time; and
determine the position of the rotating element based on the detected magnetic field pulses.

24. The position sensor of claim 16 wherein the magnet comprises a samarium-cobalt magnet.
